(19) United States
(12) Patent Application Publication
(10) Pub. No.: US 2008/0036053 A1
(43) Pub. Date: Feb. 14, 2008

(54) REINFORCED MICRO-ELECTROMECHANICAL SYSTEM PACKAGE STRUCTURE

(76) Inventors: Wan-Hua Wu, Chu-Tung (TW); Szu-Chuan Pang, Chu-Tung (TW)

Correspondence Address: SINORICA, LLC, 528 FALLSGROVE DRIVE, ROCKVILLE, MD, 20850, US

(21) Appl. No.: 11/463,594

(22) Filed: Aug. 10, 2006

(51) Int. Cl. H01L 23/495

(52) U.S. Cl. 257/666; 257/E23.043

(57) ABSTRACT

The present invention discloses a reinforced MEMS package structure, wherein after the wire-bonding process and before the molding process, an extra resin coating process is used to apply a protective resin onto the MEMS chip, the controller chip, the wires and a portion of the lead frame and provide an extra protection for the MEMS structure lest the MEMS structure be damaged by stress, thermal stress, or external force. Thereby, a reinforced MEMS package structure with a higher strength and a smaller size is achieved.

### BACKGROUND OF THE INVENTION

1. Field of the Invention

The present invention relates to a micro-electromechanical system (MEMS) package structure, particularly to a MEMS package structure reinforced with a protective resin.

2. Description of the Related Art

The silicon-chip technology has successfully realized the miniaturization of electronic systems and brought about the revolutionary advance of computers. Recently, there is also a revolutionary development for miniaturization occurring in the field of mechanical systems, wherein microelectronics and micromechanics are integrated to form microelectromechanics. Thereby, micro-electro-mechanical systems or even micro-opto-electro-mechanical systems can be realized, and the size, weight and cost of a system can be reduced, and the speed can be promoted. Microelectromechanics may be applied to the fields of information, computers, biomedicine, health care, fabrication, transportation, energy and aviation.

A MEMS chip has finer structure, lower strength and more complicated signal and is likely to be polluted by exposure or damaged by mechanical contact. When a MEMS chip is packaged with a conventional technology, the electrical functions thereof may be disabled owing to the breakage of the MEMS structure. Therefore, the packaging of a MEMS chip is more difficult than that of a silicon chip. Refer to FIG. 1 for a conventional MEMS package structure. As shown in FIG. 1, the conventional MEMS package structure comprises: a MEMS chip 10 and a controller chip 12 providing driving signal for the MEMS chip 10. The MEMS chip 10 and the controller chip 12 are connected to a lead frame 14 with wires 16. Then, via a molding process, an encapsulant 18 is used to cover the MEMS chip 10, the controller chip 12, the wires 16 and a portion of the lead frame 14 and provide protection for the abovementioned elements. However, the wires 16 and the MEMS chip 10 are very fragile, and they are very likely to break in the molding process if the molding process is not operated very carefully, and thus, the MEMS chip 10 may be unable to function.

Accordingly, the present invention proposes a reinforced MEMS package structure to overcome the conventional problem that the MEMS structure is likely to be fractured in the molding process.

### SUMMARY OF THE INVENTION

To achieve these and other advantages and in order to overcome the disadvantages of the conventional method in accordance with the purpose of the invention as embodied and broadly described herein, the present invention provides a MEMS package structure, wherein a protective resin is used to reinforce the MEMS structure and provide an extra protection for the MEMS structure to prevent the MEMS structure from being damaged during the molding process.

Another objective of the present invention is to provide a MEMS package structure, wherein the package structure can achieve a higher strength and a smaller size with the existing packaging process.

To achieve the abovementioned objectives, the present invention proposes a MEMS package structure, which comprises: a lead frame, a MEMS chip, a controller chip, a protective resin and an encapsulant, wherein the MEMS chip is electrically connected to the lead frame with wires; the controller chip is respectively electrically connected to the MEMS chip and the lead frame with wires; the MEMS chip, the controller chip, the wires and a portion of the lead frame are covered with the protective resin; and the encapsulant covers the protective resin, the MEMS chip and a portion of the lead frame.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a diagram schematically showing a conventional MEMS package structure; and

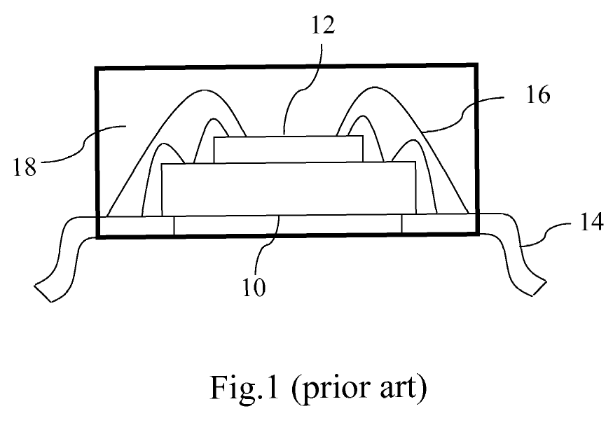

FIG. 2 is a diagram schematically showing the reinforced MEMS package structure according to one embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers are used in the drawings and the description to refer to the same or like parts.

The present invention is based on the current packaging processes, such as the processes of dicing, chip attachment, wire bonding and molding, but a resin coating process is undertaken to cover the chips, wires and a portion of the lead frame with a protective resin after the wire-bonding process and before the molding process. After the resin coating process is done, the succeeding processes, such as the molding process, are undertaken to complete the reinforced package structure.

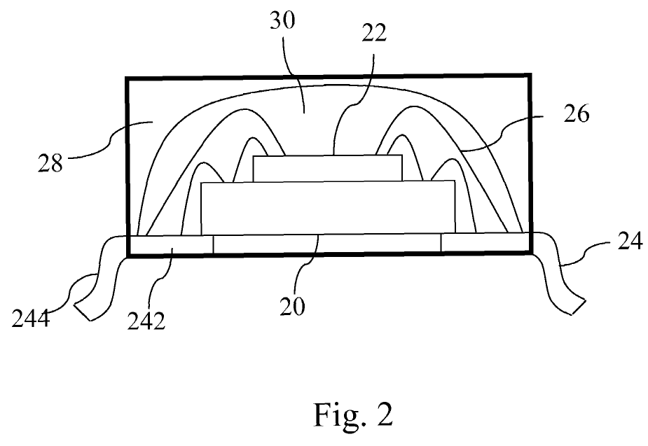

Refer to FIG. 2 a diagram schematically showing the reinforced MEMS package structure according to one embodiment of the present invention. As shown in FIG. 2, the reinforced MEMS package structure comprises: a MEMS chip 20; a controller chip 22 providing driving signal for the MEMS chip 20; a lead frame 24; a protective resin 30 and an encapsulant 28. The MEMS chip 20 is electrically connected to the inner leads 242 of the lead frame 24 with wires 26. The controller chip 22 is respectively electrically connected to the MEMS chip 20 and the inner leads 242 with wires 26. A protective resin 30 is used to cover the MEMS chip 20, the controller chip 22, the wires 26 and the inner leads 242 of the lead frame 24 and provide an extra protection for the abovementioned elements, and the entire structure is thus reinforced. The material of the protective resin 30 may be an epoxy, silicon or the like, which is compatible with the materials of the MEMS chip 20, the controller chip 22, the wires 26 and the lead frame 24. Then, an encapsulant 28 covers the protective resin 30, the bottom of the MEMS chip 20 and the inner leads 242 with the outer leads 244 of the lead frame 24 exposed. The material of the encapsulant 28 may be an epoxy.

In summary, the present invention utilizes an extra resin coating process to apply a protective resin, which functions as a buffering material to absorb stress, onto the MEMS structure before the molding process lest the MEMS structure be damaged by stress, thermal stress, or external force. Thereby, a reinforced MEMS package structure with a higher strength and a smaller size is achieved.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A reinforced micro-electromechanical system (MEMS) package structure, comprising:
a lead frame;
a MEMS chip electrically connected to said lead frame with wires;
a controller chip respectively electrically connected to said MEMS chip and said lead frame with wires and providing driving signal for said MEMS chip;
a protective resin covering said MEMS chip, said controller chip, said wires and a portion of said lead frame; and
an encapsulant covering said protective resin, said MEMS chip and a portion of said lead frame.

2. The reinforced MEMS package structure according to claim 1, wherein material of said protective resin is an epoxy or silicon.

3. The reinforced MEMS package structure according to claim 1, wherein material of said encapsulant is an epoxy.

4. The reinforced MEMS package structure according to claim 1, wherein said lead frame has inner leads and outer leads.

5. The reinforced MEMS package structure according to claim 4, wherein said wires are connected to said inner leads, and said outer leads are exposed in exterior of said encapsulant.
